(19) United States
(12) Patent Application Publication
(10) Pub. No.: US 2013/0126508 A1
(43) Pub. Date: May 23, 2013

(54) Extending Radiation Tolerance By Localized Temperature Annealing Of Semiconductor Devices

(71) Applicants: James Fred Salzman, Anna, TX (US); Charles Clayton Hadsell, Dallas, TX (US)

(72) Inventors: James Fred Salzman, Anna, TX (US); Charles Clayton Hadsell, Dallas, TX (US)

(73) Assignee: Texas Instruments Incorporated, Dallas, TX (US)

(21) Appl. No.: 13/309,393

(22) Filed: Dec. 1, 2011

Related U.S. Application Data
(60) Provisional application No. 61/561,100, filed on Nov. 17, 2011.

(51) Int. Cl. H05B 1/00; G08B 17/10; H01L 21/66

(52) U.S. Cl. 219/209; 438/15; 73/31.06; 257/E21.525

(57) ABSTRACT

A method of increasing the operating life of a semiconductor device that is to be used in a harsh ionizing radiation environment including determining heating criteria for annealing the device; installing the device in an electronic apparatus; and heating the installed device with a local heating source in accordance with the heating criteria.

This application claims priority to U.S. provisional patent application 61/561,100 for Extending Radiation Tolerance by Localized Temperature Annealing of Integrated Circuits of James F. Salzman & Charles Hadsell, filed on Nov. 17, 2011, which is hereby incorporated by reference for all that is disclosed therein.

### BACKGROUND

It is well known that ionizing radiation can cause parametric degradation and ultimately functional failures in semiconductor devices. It is also known that damage caused by ionizing radiation will sometimes spontaneously anneal (heal) over time. FIG. 1 is a prior art graph plotting CMOS transistor threshold voltage shift (Vₜ shift) data collected after the exposure of CMOS devices to ionizing radiation. The graph illustrates how CMOS devices can anneal after “total irradiated dose” exposure. Experiments at Texas Instruments has also validated this existing prior art data. At Texas Instruments CMOS devices have been exposed to 10⁵ rad of ionizing radiation over a period of about 30 minutes and then allowed to anneal, in one case at 25° C. and in a second case at 125° C. “Total irradiated dose,” also referred to as “absorbed dose” or “total ionizing dose” and abbreviated “TID” is a measure of the energy deposited in a medium by ionizing radiation over any given period of time. It is equal to the energy deposited per unit mass of medium, which may be measured as joules per kilogram and represented by the equivalent SI unit, gray (Gy), or the CGS unit, rad.

There are two dominate mechanisms associated with Vₜ shifts in the thick field and gate oxide regions of standard MOS structures of a semiconductor device under total irradiated dose. These are summarized in FIG. 1. These mechanisms (radiation induced defects) occur under ionizing radiation exposure via electron-hole pair production and transport and trapping in the dielectric and silicon interface regions of a semiconductor device. These mechanisms, known as “hole traps,” plotted in FIG. 1 by “Vₒₜ”, and interface traps, “Vᵢₜ”, have been studied for many years and are well documented. It is also well know that annealing (healing) of these mechanisms can occur over time and may be accelerated by temperature. Vₜₕ is the summation of Vₒₜ and Vᵢₜ, commonly just called Vₜ. These mechanisms are greatly affected by the particular semiconductor device structure and are highly dependent on dielectric thickness and process composition of the semiconductor device that is irradiated. Accumulation of hole traps is typically the primary mechanism for increased leakage current and failures in CMOS semiconductor devices. CMOS Semiconductor devices are typically less effected by the generation of interface traps, because the generation rate of interface traps are typically lower than hole trap generation, but the ratio of these two mechanisms are device, process, radiation rate, voltage and temperature dependent. The anneal rate of a particular device is also dependent on these variables. The total Vₜ shift and device leakage can be the summation of these effects. Some devices anneal quickly, while others may anneal at a very low rate because of these variables. Devices are often exposed to high dose rates of radiation, called accelerated exposure to determine if a given product could operate in a given radiation application. Accelerated radiation testing is often used to determine the “radiation tolerance” of a given product because the actual application may involve radiation exposure to low dose rates over months or years of exposure, and testing a part for years to determine the radiation tolerance of a device is not acceptable. As stated it is also know that a part may anneal over time.

Because of this fact, annealing of devices after radiation is often checked and is allowed under US MIL-STD-883G section 3.11.2. This calculation will determine the dose rate and radiation level the parts can be expected to work over during its intended application lifetime. For example if a part is subjected to 100 Krad TID at a rate of 50 rads/sec, under an accelerated exposure, and the part fails but heals or anneals over 1000 hours then it is permissible under this standard to divide the TID level by the anneal time and state that the part will work if exposed to 100 k Rad at a dose rate of something much less than 50 rad/second. For this example, 100 Krad divided by 1000 hours would say the part can be used in an application where it will receive a TID level of 100 Krad as long as the exposure rate is <13 mRad/sec. Accelerated exposure is used because it is not feasible to expose parts for a year or more to determine whether it they will work. As an example if a part is to be used in a space satellite application where it will receive a TID level of 100 Krad over a 15 year mission life, it would not be feasible to test parts for 15 years to determine if the part will work or not, thus a high radiation rate can be used to expose the products to the 100 Krad level, but this may cause the part to fail because there is not enough time to allow annealing.

### BRIEF DESCRIPTION OF THE DRAWINGS

FIG. 1 is a graph showing Vₒₜ/Vᵢₜ generation and time/temperature annealing.

FIG. 2 is a schematic drawing of a semiconductor device assembly.

FIG. 3 is a schematic drawing of another semiconductor device assembly.

FIG. 4 is a flow chart illustrating a method of annealing a semiconductor device.

FIG. 5 is a plan view of a wheat lamp.

FIG. 6 is a plan view of a wheat lamp mounted on a semiconductor device that is installed in a smoke detector.

FIG. 7 is a plan view of a kapton heater.

FIG. 8 is a top plan view of a kapton heater mounted on a semiconductor device that is installed in a smoke detector.

FIG. 9 is a top plan view of four resistors.

FIG. 10 is a top plan view of four heating resistors mounted on a semiconductor device that is installed in a smoke detector.

FIG. 11 is a circuit drawing of a semiconductor device heater.

FIG. 12 is a schematic drawing of one configuration of an encapsulated semiconductor device and local heat source.

FIG. 13 is a schematic drawing of another configuration of an encapsulated semiconductor device and local heat source.

FIG. 14 is a schematic drawing of yet another configuration of an encapsulated semiconductor device and local heat source.

FIG. 15 is a schematic drawing of one configuration of an encapsulated semiconductor device and local heat source mounted on a PC board.

FIG. 16 is a block diagram of an MSP430 microcontroller that is commercially available from Texas Instruments, Inc. (Dallas, Tex.).

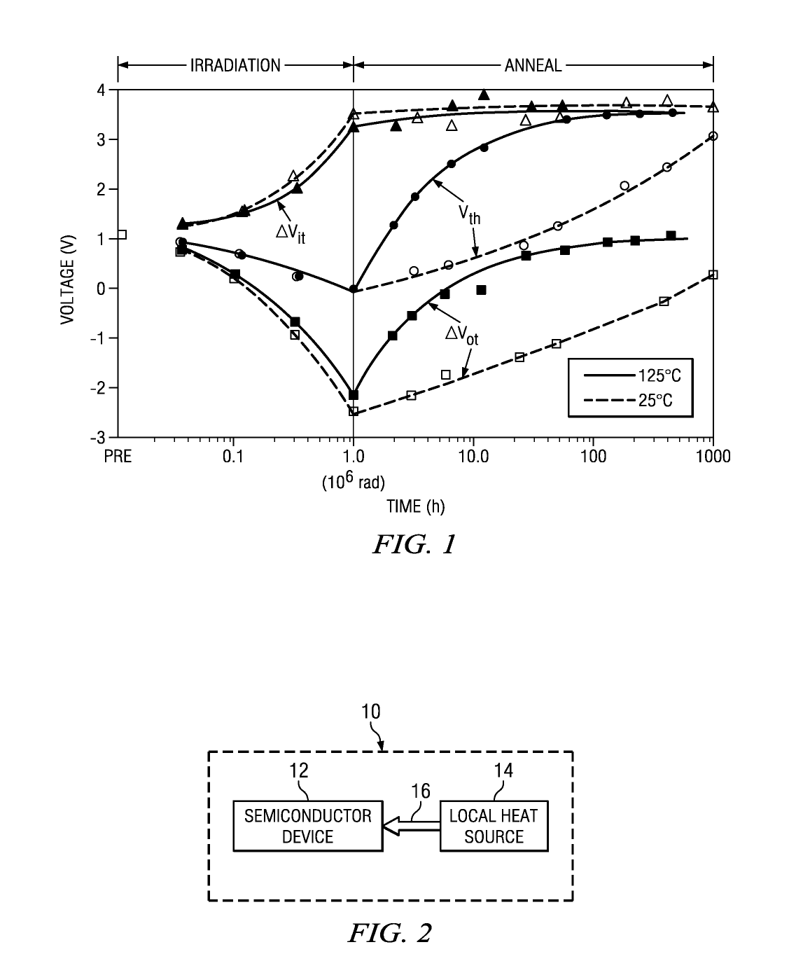

### DETAILED DESCRIPTION

To date, typically once a semiconductor device is installed in an electronic apparatus, the temperature at which it anneals from ionizing radiation damage has simply been the temperature of the environment in which the associated electronic apparatus is used. For example, if a smoke detector used in a nuclear power plant has a microcontroller that is damaged by ionizing radiation from the power plant, the temperature at which the microcontroller anneals is the temperature in the immediate environment of the smoke detector. When the annealing rate of a semiconductor device in a harsh ionizing radiation environment is relatively low, the damage caused by ionizing radiation occurs at a relatively high rate as compared to the rate of the annealing process. In other words, in such conditions radiation damage occurs much faster than it is healed. As a result, the accumulation of ionizing radiation damage will cause the semiconductor device to fail in a fairly short period of time as compared to its useful life in a normal environment.

Electronic apparatus environments having extremely high total ionizing dose (TID) conditions are sometimes referred to herein as “operating in a harsh ionizing radiation environment.” Electronic apparatus intended for use in harsh ionizing radiation environments include apparatus intended for use in nuclear power plants, particle detectors and colliders, certain medical industry machines such as X-ray machines and CAT scanners; security scanners such as used in airports, avionics, satellites, high altitude aircraft; missiles, space craft, nuclear submarines, or other environments in which a high amount of ionizing radiation is generated. For example, any environment in which over a few KRad of total ionizing radiation accumulates over the device required operational lifetime would be considered a harsh ionizing radiation environment.

Applicants have discovered that the life of some semiconductor devices used in extremely high TID conditions may be extended if the device is placed in a higher than ambient temperature environment that increases its rate of annealing. However, applicant discovered that in one situation in which the semiconductor device is a microcontroller installed is a smoke detector, that if the smoke detector is placed in an elevated temperature environment, other components of the smoke detector will be damaged by the elevated temperature. In addition, some semiconductor components can accumulate higher levels of radiation damage at elevated temperatures such as BiCMOS or bipolar semiconductors. The opposite effect under radiation can occur in certain semiconductor devices. Applicants have also discovered that by using a small localized heater, the temperature of the microcontroller device can be raised to a temperature that causes it to anneal rapidly, without damaging other components of the electronic apparatus. As a result, the microcontroller can be annealed at a rate sufficiently high to rapidly offset much of the damage caused by ionizing radiation. Thus, the operating life of the microcontroller can be substantially lengthened by such localized heating. Also, since localized heating of the microcontroller will not significantly heat other components of the smoke detector, the other components will not be damaged and the operating life of the entire smoke detector will be substantially lengthened. This same methodology may be applied to other semiconductor devices that are installed in other electronic apparatus designed to be used in harsh ionizing radiation environments.

FIGS. 2-16, in general, disclose a semiconductor device assembly 10 that includes a semiconductor device 12 and a local heater 14. The phrase “semiconductor device assembly” as used herein refers to an assembly that includes a semiconductor device and at least one additional component. In one embodiment the semiconductor device assembly 10 also includes an electronic apparatus 11 in which the semiconductor device 12 is installed. A method of increasing/extending the operating life of a semiconductor device 12 that is to be used in a harsh ionizing radiation environment is also described. The semiconductor device 12 may be selectively locally heated to increase the rate at which it anneals without causing heat damage to any nearby component(s) 42, 44 of an electronic apparatus 10, e.g., a smoke detector in which the semiconductor device 12, e.g., a microcontroller, is installed.

FIG. 2 is a schematic drawing of a semiconductor device assembly 10. The semiconductor assembly 10 includes a semiconductor device 12 and a local heater 14, which provides heat 16 to the semiconductor device 12 in accordance with certain predetermined heating criteria. The heating criteria are selected in order to anneal the semiconductor device at a satisfactorily high rate for its intended use environment. The local heat source 14 is a heat source that is adapted to provide heat primarily to the semiconductor device 12 without significantly heating adjacent structure. The local heat source has heating circuitry, described below, which is different than the primary operating circuitry (not shown) of the semiconductor device. This primary operating circuitry of the semiconductor device may be any circuitry which allows a semiconductor device to perform its primary intended function in an electronic apparatus in which it is mounted. The predetermined heating criteria, in accordance with which the heat source 14 is operated to provide a desired annealing of the semiconductor device 12, may be selected from a number of criteria. For example, one heating criteria may be a temperature to which the semiconductor device 12 is elevated. Another criteria may be the temperature of the local heating source 14. Another criterion may be continuous operation of the local heat source 14. Another criterion may be discontinuous heating of the semiconductor device 12 by turning the local heat source 14 on for a period, then off for a period, then back on, etc. The heating intervals may be of a predetermined length or may be determined by other factors such as available energy from a power source or temperature of the semiconductor device 12. As a device is being exposed to radiation, transistor leakage increases as well as transistor Vₜ shift. As a result, the part begins to draw more power, until it fails to operate, or fails permanently. Device power supply “leakage” current or product power consumption can be measured and used to determine a heating annealing algorithm.

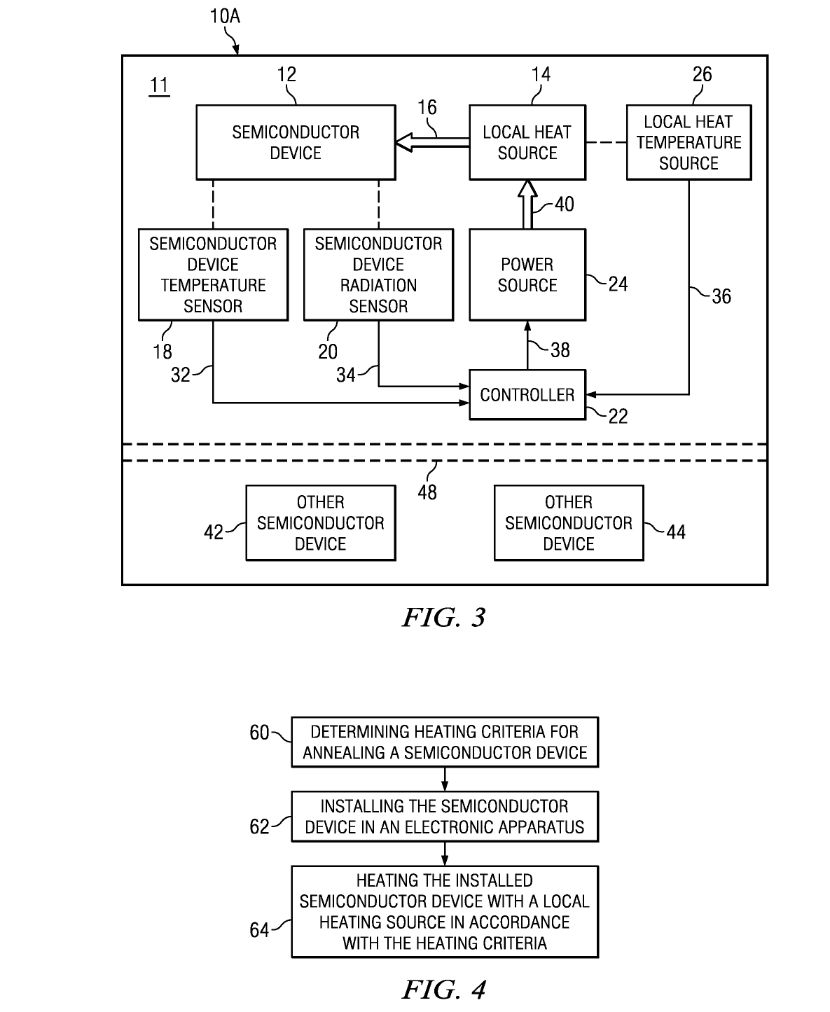

FIG. 3 illustrates another embodiment of a semiconductor device assembly 10A. Semiconductor device assembly 10A may comprise a semiconductor device 12 and a local heat source 14 that provides heat 16 to the semiconductor device 12. The semiconductor device assembly 10A may further include an electronic apparatus 11 in which the semiconductor device 12, the local heat source 14 and other components are mounted. The semiconductor device assembly 10A may also include a temperature sensor 18, a radiation level sensor 20, a controller 22, a power source 24 and a local heat source temperature sensor 26. The semiconductor device temperature sensor 18 senses the temperature of the semiconductor device 12 and generates a temperature sensor signal 32 indicative thereof which is sent to controller 22. The radiation level sensor 20 senses the radiation level within the semiconductor device 12 and generates a signal 34 in response thereto which is sent to controller 22. The local heat source temperature sensor 26 generates a signal 36 indicative of the local heat source temperature and sends a signal indicative thereof to controller 22. The controller 22 generates a control signal 38 in response to processing of the various input signals and the predetermined heating criteria. The control signal 38 causes a power source 24 to provide energy 40 to local heat source 14 which in turn provides heat 16 to the semiconductor device 12 in accordance with the predetermined heating criteria. As further illustrated by FIG. 3, other components such as semiconductor devices 42, 44 which are not as heat tolerant as semiconductor device 12 may be installed in the electronic apparatus 11. The heat applied by the local heat source 14 to the semiconductor device 12 is sufficiently localized that the other semiconductor devices 42, 44 are not detrimentally heated. For example, the heating of semiconductor 12 may be sufficiently localized so that the temperature of other semiconductor devices 42, 44, etc. within apparatus 11 are elevated less than 25%. The construction of the electronic apparatus 11, in some embodiments, also contributes to the localized heating effect. For example, an insulating heat shield 48 or the like may be installed between semiconductor device 12 and other semiconductor devices 42, 44. In other embodiments of a semiconductor device assembly various features or combinations features of the semiconductor device assembly 10A of FIG. 3 may be used to selectively locally heat a semiconductor device 12. For example in one embodiment the semiconductor temperature sensor 18, controller 22, power source 24 and local heater 14 may be used without the radiation sensor 20 or local heat source temperature sensor 26. Although certain specific semiconductor devices 12, local heat sources 14 and electronic apparatus 11 are described herein in exemplary embodiments, it is to be understood that the teachings of this disclosure are not in any way limited to such exemplary embodiments.

FIG. 4 illustrates an embodiment of a method of extending the operating life of a semiconductor device that is to be used in a harsh ionizing radiation environment. The method may include, as illustrated in block 60, determining heating criteria for annealing a semiconductor device. The method may further comprise, as illustrated in block 62, installing the semiconductor device in an electronic apparatus. As illustrated in block 64, the method may also include heating the installed semiconductor device with a local heating source in accordance with the heating criteria. Having thus described various embodiments of a semiconductor device assembly 10, 10A and a method of annealing a semiconductor device, such apparatus and method and alternative forms thereof will now be described in further detail.

FIGS. 6, 8 and 10, in general, show an electronic apparatus 11 that is a smoke detector designed for use in a harsh ionizing radiation environment. The smoke detector has a smoke detector housing 15 in which various components of the smoke detector are mounted. A semiconductor device 12 such as a microcontroller, is mounted in the smoke detector housing. The semiconductor device 12 is relatively heat tolerant. A local heat source 14 is positioned proximate the semiconductor device 12 and is adapted to heat the semiconductor device 12 in a manner that significantly increases the annealing rate of the semiconductor device 12 without causing other components in the smoke detector that are not heat tolerant to fail prematurely. Various specific embodiments of the smoke detector are described below with reference to FIGS. 6, 8 and 10.

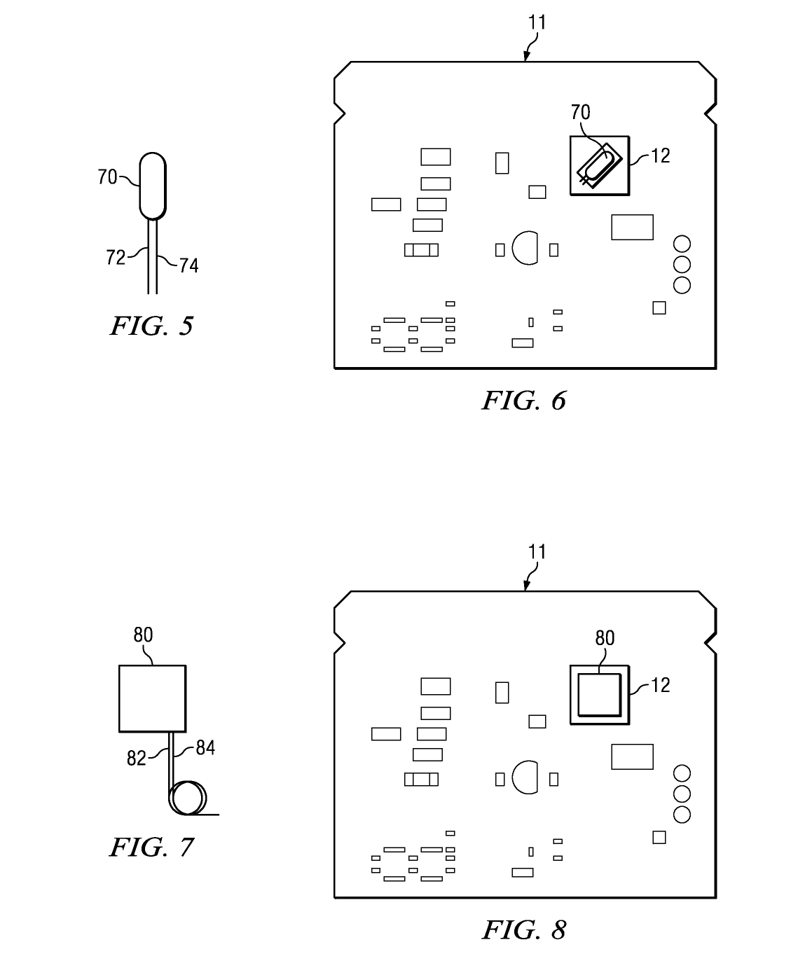

The local heat source 14 described above in reference to FIGS. 2 and 3 may be, as illustrated in FIG. 5, a wheat lamp 70 having leads 72, 74 and which may be connected to a power source. FIG. 6 illustrates an electronic apparatus 11, which may be a smoke detector. Smoke detectors are described in the following U.S. patent application Publications which are hereby incorporated by reference for the smoke detector descriptions provided therein: U.S. Patent Application Publication Numbers 20110260876 for Light Receiver Device Having A Shielding Device Extending On A Back Side Of A Substrate; 20110255091 for Adapting A Scanning Point Of A Sample And Hold Circuit Of An Optical Smoke Detector; 20090256714 for Device and Method for Detecting Smoke by Joint Evaluation of Two Optical Backscatter Signals; 20080266558 for Scattered Light Smoke Detector; and 20060017580 for Scattered Light Smoke Detector. The smoke detector referred to in FIGS. 6, 8 and 10 may have the same basic structures and operational features of any of the smoke detectors describe in the above referenced patent applications or of any other smoke detector, now known or later developed. The smoke detector (electronic apparatus 11) has a semiconductor device 12 installed therein. The semiconductor device 12 in this embodiment may be a microcontroller such as, by way of example and not limitation, the microcontroller sold under product designation MSP430, or equivalent microcontroller available from Texas Instruments, Inc. of Dallas, Tex. This microcontroller may be provided on a microcontroller die in an integrated circuit (“IC”) package in which the microcontroller die is encapsulated in mold compound or the like. A wheat lamp 70 may be adhered to a surface of this IC package and has leads 72, 74 thereof (not shown in FIG. 6) attached to a power supply line (not shown) located within the proximity of the smoke detector. In this particular embodiment, the heating criteria used is continuous heating of the semiconductor device 12 by continuous supply of power to the wheat lamp, which may have, for example, a 15 volt bulb. The heat output provided by the wheat lamp 70 is sufficiently high to increase the annealing rate of the semiconductor device to a predetermined rate based upon the intended use environment of the smoke detector, but is sufficiently small and localized that other components of a smoke detector are not detrimentally heated. For example, in one embodiment the microcontroller is heated to and continuously maintained at a temperature of about 100° C.

FIG. 7 illustrates a kapton heater 80 having leads 82, 84. FIG. 8 illustrates an electronic device 11 which may be a smoke detector having a housing 15 and having an installed semiconductor device 12 which may be a microcontroller that is positioned inside the housing 15. The kapton heater 80 is mounted on an exposed surface of the smoke detector (semiconductor device 12) as by adhesive and is connected to a power line. The kapton heater 80 provides continuous localized heating of the semiconductor device 12 without significantly heating any adjacent semiconductor devices.

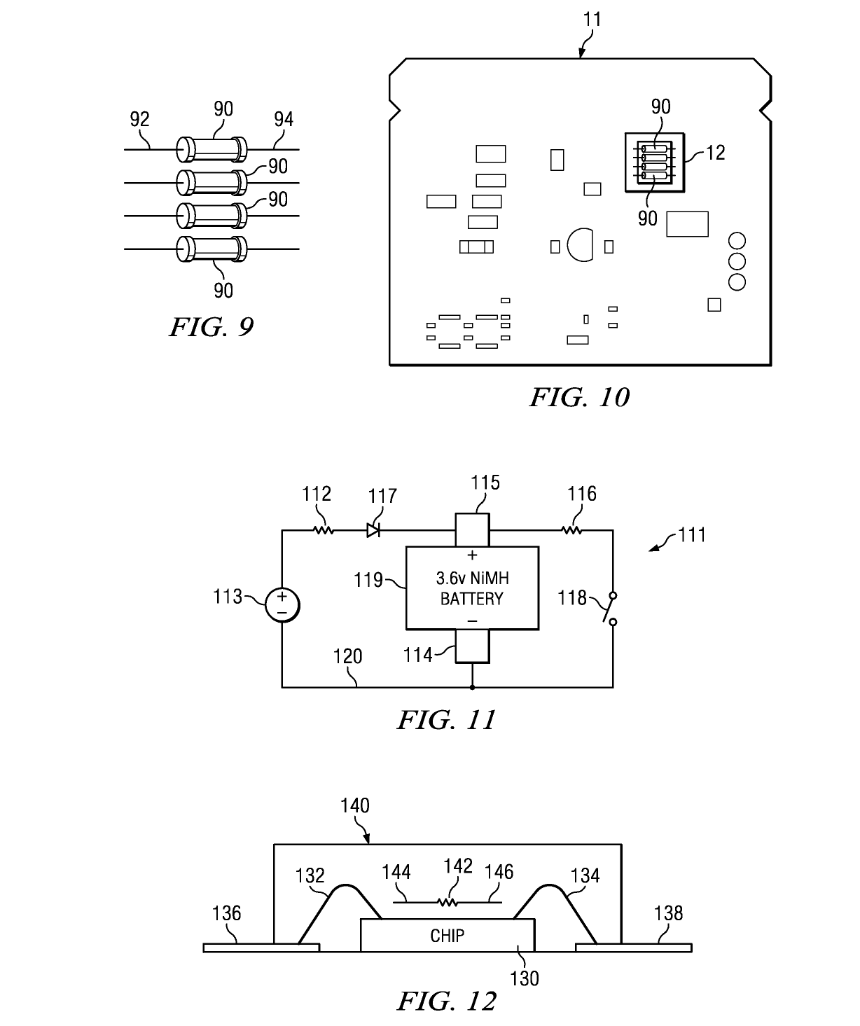

Another embodiment of a local heat source is, as illustrated by FIG. 9, includes a resistive element, which in the embodiment of FIG. 9 is four resistors 90 which may be connected in parallel to a power source by leads 92, 94 connected to each of the resistors 90. FIG. 10 illustrates a smoke detector in which the parallel resistors are mounted on a semiconductor device 12 which may be a microcontroller. The resistors 90 may be mounted, as by adhesive, to a surface of the semiconductor device 12. The resistors 90, in one embodiment, are each approximately two-watt resistors that are operably connected to a constantly “on” power source.

FIG. 11 illustrates an embodiment of a circuit 111 that may supply sufficiently high power to a local heat source in a situation where limited power is available to the circuit. FIG. 11 further illustrates a switching circuit which may be used with the wheat lamp 70, kapton heater 80, or resistors 90, described above, or with any other heat source. The circuit 111 includes a power source 113. In the embodiment of FIG. 11, the power source 113 is a DC power source having a positive terminal and a negative terminal. In some embodiments, the power source 113 may be an AC power source.

The negative terminal of the power source 113 is connected to a common line or ground 120 in the circuit 111. The positive terminal of the power source 113 is connected to a resistor 112. The resistor, in turn is connected to the anode of a diode 117. The cathode of the diode is connected to the positive terminal 115 of a battery 119. The negative terminal 114 of the battery 119 is connected to the ground 120 of the circuit 111. The positive terminal 115 of the battery 119 is also connected to a heating element 116, which in the embodiment of FIG. 11 is a resistive element. The heating element is connected to a switch 118 that is controlled by a timer or other control device. The switch 118 may be an electronic switch, such as a FET. In one embodiment the switch is an electronic switch that is actuated by a control signal from a Texas Instruments MSP430 microcontroller.

The power source 113 provides a charging current to the battery 119 by way of the resistor 112 and the diode 117. The resistor 112 limits the current drawn on the power supply 113 by the batter 119. The diode 117 prevents current from leaking from the battery 119 to the power supply 113. The diode may also rectify the power used to charge the battery 119 in the event that the power supply 113 is an AC power supply.

When the battery 119 is charged, it is able to provide more power to the heating element 116 than the power supply 113 is able to provide. The heating element 116 is activated by closing the switch 118, which causes current to flow from the positive terminal 115 of the battery 119, through the heating element 116, through the switch 118 and back to the negative terminal 114 of the battery 119.

Various arrangements of a resistive heater and semiconductor device are illustrated in FIGS. 12 through 15.

FIG. 12 illustrates a semiconductor device 130 having bond wires 132,134 attached to package leads 136, 138. The semiconductor device 130 and portions of the package leads 136, 138 are positioned within an encapsulation 140 which may be provided by epoxy or other encapsulation material. A resistive heater 142 is attached to a power source (not shown) by conductors 144,146. The power source provides electric current to heat the resistive heater 142 in accordance with predetermined heating criteria. The resistive heater 142 in this embodiment is positioned within the encapsulation 140.

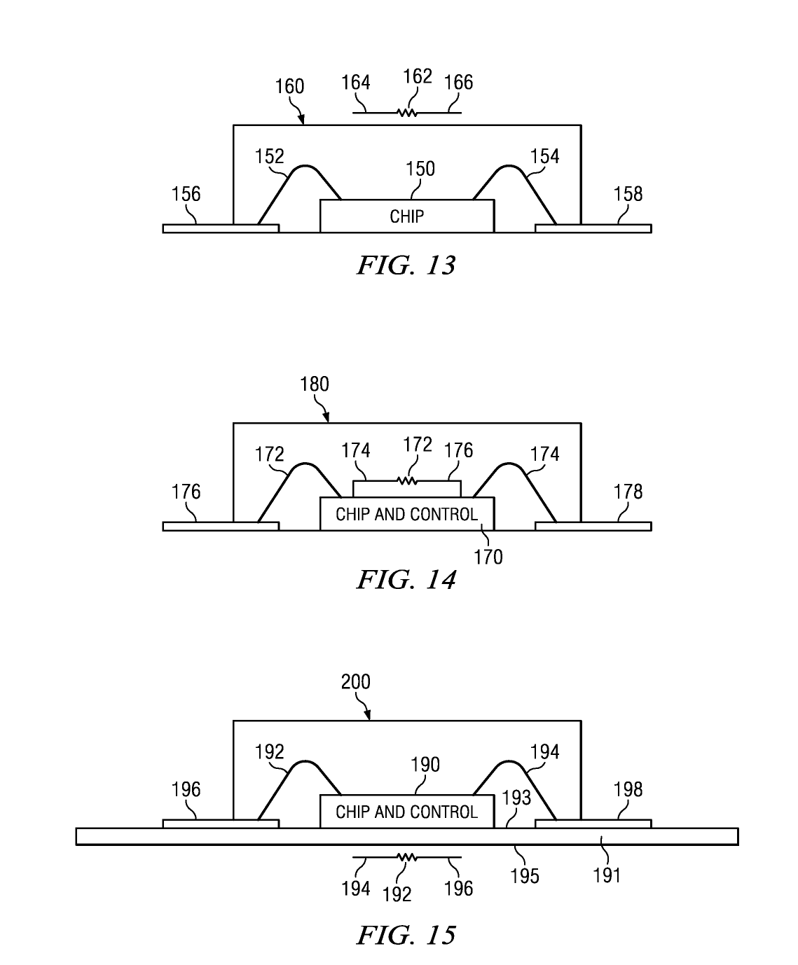

FIG. 13 illustrates a semiconductor device 150 having bond wires 152,154 attached to package leads 156, 158. The semiconductor device 150 and portions of the package leads 156, 158 are positioned within an encapsulation 160 which may be provided by epoxy or other encapsulation material. A resistive heater 162 is attached to a power source (not shown) by conductors 164,166. The power source provides electric current to heat the resistive heater 162 in accordance with predetermined heating criteria. The resistive heater 162 is positioned outside and immediately adjacent to the encapsulation 160 in this embodiment.

FIG. 14 illustrates a semiconductor device 170 having bond wires 172,174 attached to package leads 176, 178. The semiconductor device 170 and portions of the package leads 176, 178 are positioned within an encapsulation 180 which may be provided by epoxy or other encapsulation material. A resistive heater 182 is attached to a power source, which is integral with the semiconductor device, by conductors 184,186. The power source (not shown) provides electric current to heat the resistive heater 182 in accordance with predetermined heating criteria. The resistive heater 182 is positioned within the encapsulation 180. Control of the power source in accordance with the heating criteria, in this embodiment, is provided by separate control circuitry located in the semiconductor device 190 itself or connected to the semiconductor device 190.

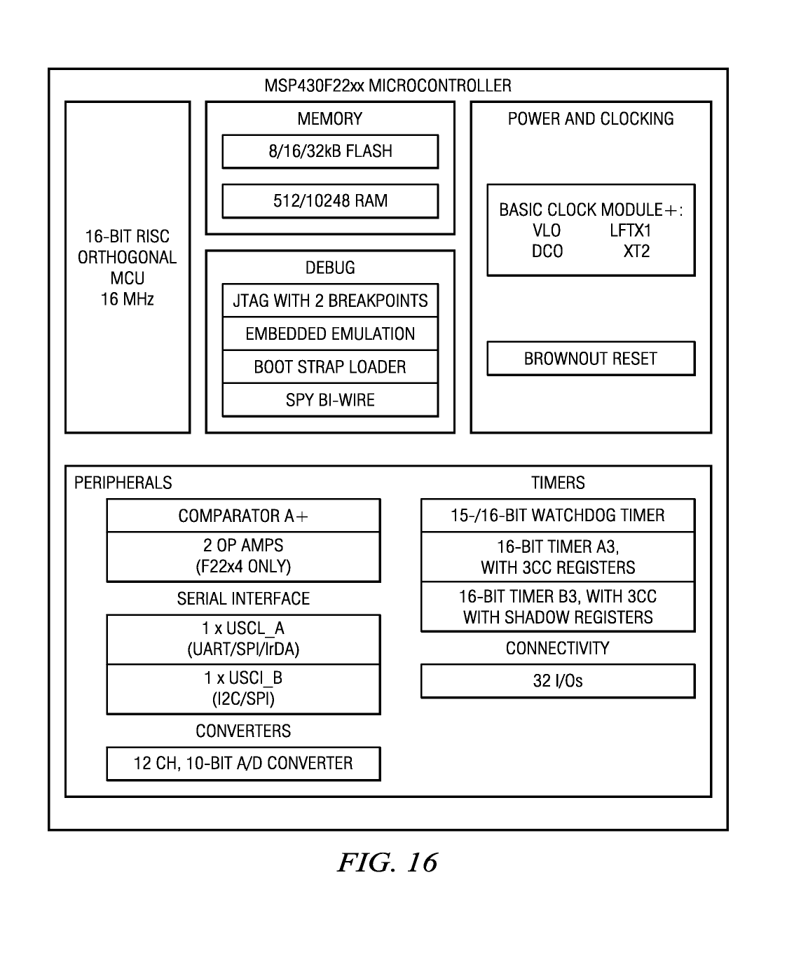

FIG. 15 illustrates a semiconductor device 190 having bond wires 192,194 attached to package leads 196, 198. The semiconductor device 190 and portions of the package leads 196, 198 are positioned within an encapsulation 200 which may be provided by epoxy or other encapsulation material. A resistive heater 202 is attached to a power source by conductors 204,206. The power source (not shown) provides electric current to heat the resistive heater 202 in accordance with predetermined heating criteria. The semiconductor device 190 and package leads 196, 198 are mounted on a first side of a PC board 191 having a first side 193 and an opposite second side 195. The resistive heater 202 is positioned adjacent to the second side 195 of the PC board 191 in alignment with the semiconductor device 190 mounted on the first side 193.

Although the local heat sources 14 in the above described embodiments are each mounted in close proximity to the associated semiconductor devices 12 it is to be understood that a local heat source may be positioned remotely from the semiconductor device 12 so long as it applies heat to it locally. For example, a local heat source 14 could focus a beam of light on a semiconductor device 12 from a source, such as a laser, positioned remotely from the semiconductor device.

It will be understood from the above description that the design of a semiconductor assembly that is to be used in a harsh ionizing radiation environment involves a number of tradeoffs. The annealing rate of the semiconductor device 12 must be sufficiently high to anneal much or most of the damage being caused to the device by the ionizing radiation. Accordingly the heating of the device 12 must be designed to provide this annealing rate. Also, the annealing temperature to which the device 12 is raised must not be so high that it causes the device 12 to fail prematurely. Also, the annealing temperature must not be so high that it causes premature failure of other components in the electronic apparatus 11 in which the semiconductor device 12 is mounted. Another consideration is the structure and composition of the particular semiconductor device and specific temperature and heating conditions at which that particular semiconductor device 12 anneals best. Another consideration is the available power source. For example in some situations continuous power may not be available. All of these considerations or particular ones that are most important in any particular situation may be used to determine the heating profile of the semiconductor device 12 and the heating criteria to be applied to obtain that heating profile.

Although certain embodiments of the invention have been specifically described herein, many alternative embodiments will be apparent to those skilled in the art after reading this disclosure. It is intended that the appended claims be construed to encompass all such alternative embodiments, except to the extent limited by the prior art.

What is claimed is:

1. A method of increasing the operating life of a semiconductor device that is to be used in a harsh ionizing radiation environment comprising:
determining heating criteria for annealing the device;
installing the device in an electronic apparatus; and
heating the installed device with a local heating source in accordance with the heating criteria.

2. The method of claim 1 further comprising sensing the temperature of the semiconductor device.

3. The method of claim 1 further comprising sensing the radiation level in or around the semiconductor device.

4. The method of claim 1 wherein said determining the heating criteria comprises determining a device target temperature.

5. The method of claim 1 wherein said determining the heating criteria comprises determining a local heating source target operating temperature.

6. The method of claim 1 wherein said determining the heating criteria comprises determining a local heating source continuous activation period.

7. The method of claim 1 wherein said determining the heating criteria comprises determining a local heating source activation pattern.

8. The method of claim 1 wherein said heating the device with a local heating source comprises heating the device with a heating source separate from the device and mounted on the device.

9. The method of claim 1 wherein said heating the device with a local heating source comprises heating the device with a heating source separate from the device and mounted on a circuit board adjacent to the device.

10. The method of claim 1 wherein said heating the device with a local heating source comprises heating the device with a heating source separate from the device and encapsulated with the device.

11. The method of claim 1 wherein said heating the device with a local heating source comprises heating the device with a heating source separate from the device and directing radiant heat onto the device from a spaced apart location.

12. The method of claim 1 wherein said heating the device with a local heating source comprises heating the device with a heating source that is integral with the device.

13. The method of claim 1 wherein said heating the device with a local heating source comprises heating the device with a heating source separate from the device which does not raise the temperature of any other semiconductor device installed in the apparatus by more than about 5° C.

14. A semiconductor device assembly comprising:
a semiconductor device having operating circuitry;
a local heat source positioned proximate said semiconductor device and adapted to heat said semiconductor device and having heating circuitry separate from said semiconductor device operating circuitry;
said local heat source being operable in accordance with predetermined heating criteria selected to provide a desired annealing of said semiconductor device.

15. The semiconductor device assembly of claim 14 further comprising an electronic apparatus and wherein said semiconductor device and said local heat source are installed in said electronic apparatus.

16. The semiconductor device assembly of claim 14 further comprising a heat source controller operably connected to said heat source, said heat source controller operating said heat source in accordance with said predetermined heating criteria.

17. The semiconductor device assembly of claim 16 further comprising a semiconductor device temperature sensor operably connected to said heat source controller.

18. The semiconductor device assembly of claim 16 wherein at least one of said heat source and said heat source controller is integral with said semiconductor device.

19. The semiconductor device assembly of claim 14 wherein said heat source is not electrically connected to said semiconductor device.

20. A smoke detector for use in a harsh ionizing radiation environment comprising:
a smoke detector housing;
a semiconductor device mounted in said smoke detector housing; and
a local heat source positioned proximate said semiconductor device and adapted to heat said semiconductor device in a manner that significantly increases the annealing rate of said semiconductor device without causing other components in said smoke detector to fail prematurely.
